(19) United States
(12) Patent Application Publication
(10) Pub. No.: US 2006/0086950 A1
(43) Pub. Date: Apr. 27, 2006

(54) Method for making a passivated semiconductor substrate

(76) Inventors: Matty Caymax, Leuven (BE); Renaud Bonzom, Levignac sur Save (FR); Frederik Leys, Gent (BE); Marc Meuris, Keerbergen (BE)

Correspondence Address: MCDONNELL BOEHNEN HULBERT & BERGHOFF LLP, 300 S. WACKER DRIVE, 32ND FLOOR, CHICAGO, IL, 60606, US

(21) Appl. No.: 11/249,642

(22) Filed: Oct. 13, 2005

Related U.S. Application Data
(60) Provisional application No. 60/618,863, filed on Oct. 13, 2004.

(51) Int. Cl. H01L 29/732

(52) U.S. Cl. 257/183

(57) ABSTRACT

The present invention is related to a method for making a passivated semiconductor substrate comprising the steps of providing a substrate surface comprising or consisting of mono-crystalline semiconductor material other than silicon and forming a silicon layer on the substrate surface, such that the silicon layer is substantially lattice matched to the mono-crystalline semiconductor material. It is also related to a semiconductor substrate passivated according to the method.

### CROSS-REFERENCE TO RELATED APPLICATION

This application claims priority under 35 U.S.C. § 119(e) to U.S. Provisional Application No. 60/618,863, filed Oct. 13, 2004. The above-referenced prior application is incorporated by reference herein in its entirety and is hereby made a portion of this specification.

### FIELD OF THE INVENTION

This invention relates to method for passivation of a semiconductor substrate comprising a semiconductor material other than silicon.

It also relates to a semiconductor device comprising such a passivated semiconductor substrate.

### BACKGROUND OF THE INVENTION

In the microelectronics industry, a lot of different semiconductor materials are used besides Silicon (Si). For example, Germanium (Ge) wafers are important substrates with technological applications in optical devices and have been recently introduced as a replacement for Si substrates for advanced Integrated Circuit (IC) devices. Ge has very attractive advantages such as high mobility and compatibility with high-k and III/V materials.

Gallium arsenide (GaAs) is another example of a semiconductor material, a so-called III/V material. This material is often used in optical devices such as LEDs, sensors, and the like.

When processing wafers containing these alternative materials, dedicated process conditions have to be developed.

Especially in case of deposition of gate stacks on Ge, one has to deal with a lot of difficulties and challenges. One of the major problems is the high interface states density (Nᵢₜ) at the interface between the Ge substrate and the gate dielectric, causing a bad capacitance-voltage (C-V curve) and current density-voltage (I-V curve) device characteristics.

Also, for analysis of the mentioned alternative semiconductor materials, especially in the case of Spreading Resistance measurements, the problem of high interface states density can influence the measurement.

A few attempts to decrease the problems associated with high interface states density between Ge substrate and gate oxide are known in prior art.

In “A TaN—HfO₂—Ge pMOSFET with novel SiH₄ surface passivation”, Wu et al. teach a method for passivating a Ge layer, wherein an amorphous interfacial layer is deposited in SiH₄ ambient.

In U.S. Pat. No. 6,352,942, Luan et al. teach a method of oxidation of Si on Ge, wherein a 35 nm polycrystalline Si layer was deposited and then oxidized by exposure to dry oxygen gas.

### SUMMARY OF THE INVENTION

The preferred embodiments aim to provide a method for passivating a semiconductor substrate comprising semiconductor material other than silicon in relation to further IC processing.

The present description discloses a method for making a passivated semiconductor substrate comprising the steps of providing a substrate surface comprising or consisting of a mono-crystalline semiconductor material other than silicon and forming a silicon layer on the substrate surface, such that the silicon layer is substantially lattice matched to the mono-crystalline semiconductor material.

The mono-crystalline semiconductor substrate surface can comprise or can consist of any semiconductor material other than silicon, more particularly Ge, GaAs, or any combination thereof.

In a method according to the present description, the silicon layer passivates the substrate surface in relation to subsequent IC processing.

In a method according to the present description, the thickness of the formed silicon layer can be selected such that during and after at least one subsequent IC processing step the silicon layer still passivates the substrate surface in relation to further IC processing.

After said at least one subsequent IC processing step, the thickness can be 1 to 6 monolayers, 1 to 4 monolayers, 1 to 2 monolayers, or 1 monolayer. However, in certain embodiments the thickness can be higher.

Subsequent IC processing can comprise a processing step such as but not limited to oxidation of a part of the silicon layer, formation of a dielectric layer stack, or formation of a gate stack.

A method according to the present description can further comprise the step of rendering the semiconductor substrate substantially free of oxides before the step of forming the silicon layer.

In a method according to the present description, the silicon layer can be formed by epitaxial growth.

As silicon precursor silane, dichlorosilane, trisilane, or the like, or a combination thereof can be used. H₂ and preferably N₂ can be used as carrier gas. In a preferred method the silicon layer is formed with trisilane as silicon precursor and N₂ as carrier gas.

The present description provides further a semiconductor substrate passivated according to the method of the present description. This passivated semiconductor substrate can be used in a semiconductor device.

This passivated substrate surface can have an Omhic current-voltage profile which can be measured by Spreading Resistance analysis techniques.

### BRIEF DESCRIPTION OF THE DRAWINGS

FIG. 1: TEM picture of a high-k gate stack on Ge passivated with silicon.

FIG. 2: Schematic description of a high-k gate stack on Ge passivated with silicon.

FIG. 3: C-V measurement of a p-type Ge capacitor fabricated in 3 different ways

FIG. 4: I-V curve of a p-type Ge capacitor fabricated with and without epitaxial silicon layer

FIG. 5: Nᵢₜ comparison for Si passivated and NH₃ anneal passivated Ge n- and p-FETs.

FIG. 6: Low field effective mobility μ_{eff} and corresponding I_{S}-V_{G} characteristics of 10 μm and 0.15 μm n-FETS.

FIG. 7: Low field effective mobility μ_{eff} and corresponding I_{S}-V_{G} characteristics of 10 μm and 0.15 μm p-FETS.

FIG. 8: SRP current-voltage profile with and without silicon passivation layer.

### DETAILED DESCRIPTION OF THE PREFERRED EMBODIMENT

To solve the problem of high interface states density, a method for making a passivated semiconductor substrate is disclosed comprising the steps of providing a substrate surface comprising or consisting of mono-crystalline semiconductor material other than silicon and forming a silicon layer on the substrate surface, such that the formed silicon layer is substantially lattice matched to said mono-crystalline semiconductor material.

The mono-crystalline semiconductor substrate can comprise or can consist of any semiconductor material other the Si, more particularly Ge, GaAs, or any combination thereof.

In a method according to the preferred embodiments, the silicon layer passivates the substrate surface in relation to subsequent IC processing.

In the context of the preferred embodiments, passivation can be defined as making semiconductor material other than silicon chemically and electrically stable in relation to subsequent IC processing by reaction with silicon.

In a method according to the preferred embodiments, the thickness of the formed silicon layer can be selected such that during and after at least one subsequent IC processing step the silicon layer still passivates the substrate surface in relation to further IC processing.

After said at least one subsequent IC processing step, the thickness can be 1 to 6 monolayers, 1 to 4 monolayers, 1 to 2 monolayers, or 1 monolayer. However, in certain embodiments the thickness can be higher. In case of Ge devices, after gate oxide formation 1 monolayer could be enough to avoid contact between Ge and the gate oxide and have minimal influence on the Equivalent Oxide Thickness (EOT).

The required silicon layer thickness can also be obtainable by providing a thicker layer than required, followed by oxidizing the silicon, or any other technique to decrease the silicon layer thickness, leaving the required number of monolayers of silicon. The required thickness can also be provided directly by a dedicated deposition process.

Forming the silicon layer substantially lattice matched to the substrate surface could be done in different ways. One way could be epitaxial growth of silicon. Another possibility could be providing a non-epitaxial layer, followed by re-crystallization of the layer in order to make it lattice matched to the substrate surface.

The silicon layer could be provided by different chemical vapor deposition techniques using a silicon precursor e.g. silane, dichlorosilane, trisilane or the like. Preferably, epitaxial growth could be used, because this technique is able to form the silicon layer directly substantially lattice matched to the substrate surface.

In case of LPCVD epitaxial growth, the silicon precursor could be silane, dichlorosilane, trisilane or the like, or a combination thereof. As a carrier gas, H₂ or preferably N₂ could be used. The deposition temperature can be 300 to 600° C. depending on the silicon precursor and pressure can be between 10 torr (13.3 mbar) and 100 torr (133.3 mbar). In a preferred method the silicon layer is formed with trisilane and N2 as carrier gas at 300° C.

Rendering the semiconductor substrate surface substantially oxide free before forming the silicon layer could be done by subjecting the semiconductor surface to a solution containing HF, HBr, HI or any combination thereof, optionally followed by an annealing step in hydrogen ambient.

An additional advantage of the preferred embodiments is that, in case of fabricating devices on semiconductor substrates other than silicon, the process flow can be simplified by changing it partially into IC processing on silicon.

### EXAMPLE 1

In order to make a Ge capacitor, a gate stack is deposited on top of the Ge channel. To avoid a high interface state density at the interface between the Ge channel and the gate oxide, the Ge surface is passivated by forming a substantially lattice matched monolayer of silicon on top of it. This is done by growing a few monolayers of mono-crystalline silicon in an epireactor, e.g. ASM epsilon, at a temperature between 500 and 575° C., with 20 to 50 sccm silane, a pressure of 40 torr (53.3 mbar) and 10 to 40 slm N₂ as carrier gas. This mono-crystalline silicon layer is formed substantially lattice matched to the Ge.

In order to be able to grow epitaxially on the Ge surface and to remove substantially all germanium oxide on top of it, a surface preparation is done. Therefore, the Ge surface is subjected to a 1% HF solution, followed by anneal in H₂ ambient inside the chamber of the epireactor at a temperature between 650 and 850° C.

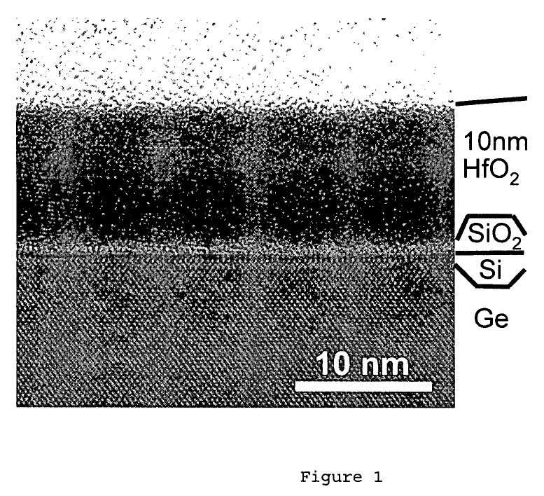

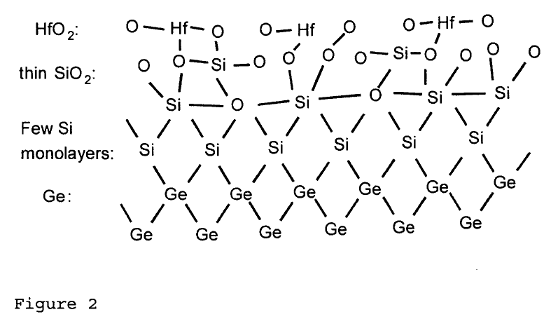

After the mono-crystalline growth of 4 to 5 monolayers of silicon, the gate oxide is fabricated. This is done by oxidizing the silicon layer thermally, thereby leaving 1 to 2 monolayers of silicon between the Ge and the gate oxide, followed by depositing High-k material. FIG. 1 shows a TEM picture of the resulting structure. FIG. 2 describes such structure schematically.

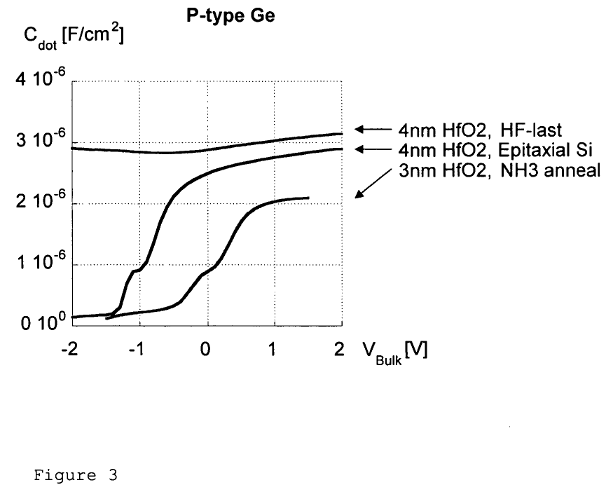

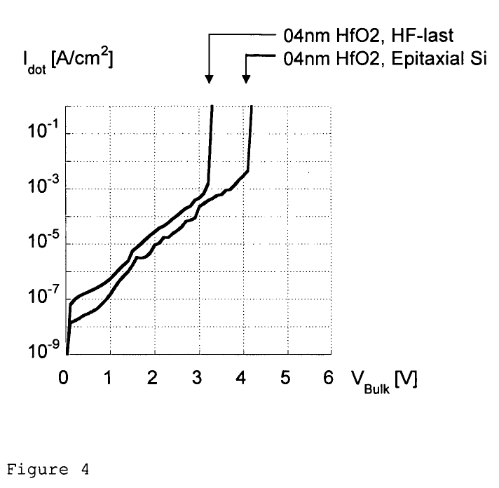

FIG. 3 shows a C-V measurement of a p-type Ge capacitor fabricated in 3 different ways. In case an epitaxial silicon layer is present between the Ge and the gate oxide, the C-V curve shows a much more pronounced slope compared to the cases where this silicon layer is not present. This indicates that, in case of the presence of the silicon layer, the interface states density (Nit) at the Ge/gate oxide interface is decreased. FIG. 4 shows the I-V curve of a p-type Ge capacitor fabricated with and without epitaxial silicon layer. In case the silicon layer is present, the breakdown voltage increases approximately 1 Volt.

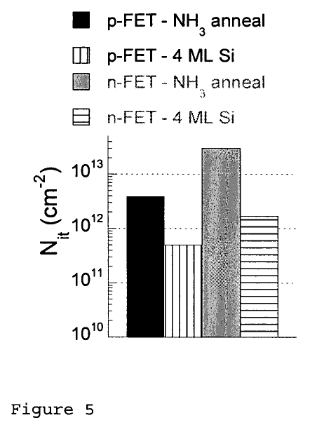

Also 10 μm*10 μm Ge n- and p-FET devices with four monolayers of silicon are fabricated. Charge pumping measurements on these devices confirm the reduced amount of Nᵢₜ as compared to an NH₃ anneal passivation treatment, which is a commonly used technique. In FIG. 5 is shown that the reduction is about one decade, yielding values of 5e11 cm⁻² for p-FET and 1.5e12 cm⁻² for n-FET.

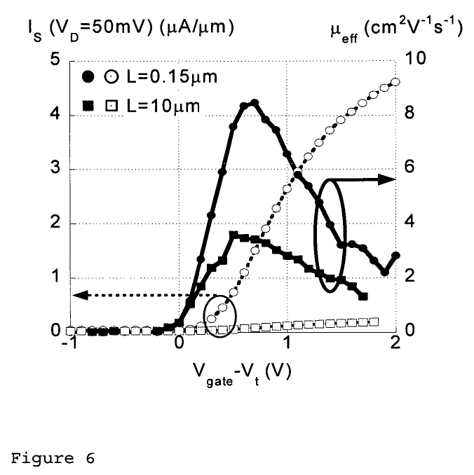

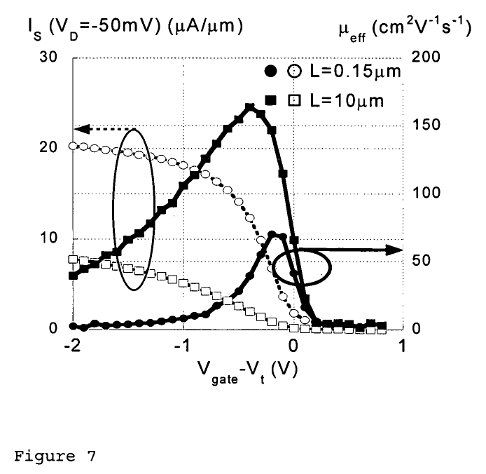

As a consequence of the lower Nᵢₜ, device lots with Si passivation yield promising deep-sub micron n- and p-FET devices. Their low field effective mobility μ_{eff} and corresponding I_{S}-V_{G} characteristics are shown in FIG. 6 and 7. The p-FET mobility obtained in silicon passivated conventional 10 μm and 0.15 μm devices is in line with the values obtained with NH₃ or PH₃ passivation on ring-shaped long channel devices (Table 1). The n-FET mobility is still low, although significantly superior to the data published for NH₃ passivation. Good n-FET mobility has only been reported for the PH₃ passivation.

Table 1 provides a comparison of the low field mobility μ_{eff} and the EOT between silicon passivated devices and relevant publications for p- and n-FETs.

TABLE 1

| | p-FET | | n-FET | |
|---|---|---|---|---|
| | μ_{eff}(cm²/Vs) | EOT (Å) | μ_{eff}(cm²/Vs) | EOT (Å) |
| Si passivated | 170 | 26 | 10 | 26 |
| NH3 | 210 | 16 | ˜0.2 | ? |
| PH3 | 125 | 17? | 300 | 17? |

### EXAMPLE 2

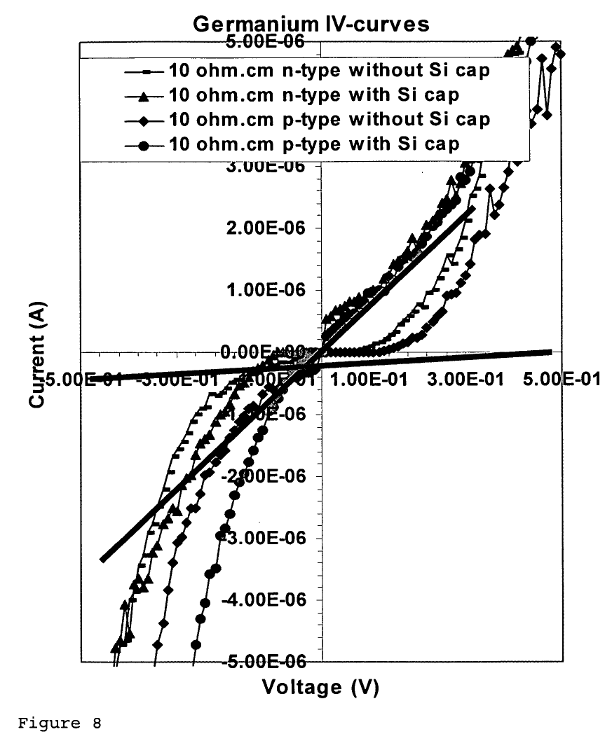

In the case of Spreading Resistance analysis, e.g., SRP (Spreading Resistance Probing) and SSRM (Scanning Spreading Resistance Microscopy), on doped Ge substrates, point contacts are realized between the metal probe and the Ge surface. When contacting the Ge directly with the probe, a Shottky contact is created due to generation of a depletion layer at the Ge side. When passivating the doped Ge substrate with a mono-crystalline undoped silicon layer of the preferred embodiments, the Shottky contact is modified into a substantially Ohmic contact. FIG. 8 proofs that doped Ge samples with an epitaxially grown mono-crystalline silicon layer of two monolayers thickness show an approximately Ohmic current-voltage profile compared to the samples without silicon layer. This simplifies Spreading Resistance analysis and improves its accuracy to a high extend.

All references cited herein are incorporated herein by reference in their entirety. To the extent publications and patents or patent applications incorporated by reference contradict the disclosure contained in the specification, the specification is intended to supersede and/or take precedence over any such contradictory material.

The term “comprising” as used herein is synonymous with “including,” “containing,” or “characterized by,” and is inclusive or open-ended and does not exclude additional, unrecited elements or method steps.

All numbers expressing quantities of ingredients, reaction conditions, and so forth used in the specification and claims are to be understood as being modified in all instances by the term “about.” Accordingly, unless indicated to the contrary, the numerical parameters set forth in the specification and attached claims are approximations that may vary depending upon the desired properties sought to be obtained by the present invention. At the very least, and not as an attempt to limit the application of the doctrine of equivalents to the scope of the claims, each numerical parameter should be construed in light of the number of significant digits and ordinary rounding approaches.

The above description discloses several methods and materials of the present invention. This invention is susceptible to modifications in the methods and materials, as well as alterations in the fabrication methods and equipment. Such modifications will become apparent to those skilled in the art from a consideration of this disclosure or practice of the invention disclosed herein. Consequently, it is not intended that this invention be limited to the specific embodiments disclosed herein, but that it cover all modifications and alternatives coming within the true scope and spirit of the invention as embodied in the attached claims.

What is claimed is:

1. A method for making a passivated semiconductor substrate, comprising the steps of:
providing a substrate surface comprising a mono-crystalline semiconductor material other than silicon; and
forming a silicon layer on the substrate surface, such that the silicon layer is substantially lattice matched to said mono-crystalline semiconductor material.

2. A method according to claim 1, wherein the mono-crystalline semiconductor material is selected from the group consisting of Ge, GaAs, and combinations thereof.

3. A method according to claim 1, wherein the silicon layer passivates the substrate surface in relation to a subsequent IC processing step.

4. A method according to claim 1, further comprising conducting at least one subsequent IC processing step, wherein a thickness of the silicon layer is selected such that during and after the subsequent IC processing step the silicon layer passivates the substrate surface in relation to a further IC processing step.

5. A method according to claim 1, further comprising conducting at least one subsequent IC processing step, wherein after the subsequent IC processing step the thickness of the silicon layer is from 1 to 6 monolayers.

6. A method according to claim 1, further comprising conducting at least one subsequent IC processing step, wherein after the subsequent IC processing step the thickness of the silicon layer is from 1 to 4 monolayers.

7. A method according to claim 1, further comprising conducting at least one subsequent IC processing step, wherein after the subsequent IC processing step the thickness of the silicon layer is from 1 to 2 monolayers.

8. A method according to claim 1, further comprising conducting at least one subsequent IC processing step, wherein after the subsequent IC processing step the thickness of the silicon layer is 1 monolayer.

9. A method according to claim 3, wherein the subsequent IC processing step comprises at least one step selected from the group consisting of oxidation of a part of the silicon layer, formation of a dielectric layer stack, and formation of a gate stack.

10. A method according to claim 1, further comprising a step of rendering the semiconductor substrate surface substantially free of an oxide before the step of forming a silicon layer.

11. A method according to claim 1, wherein the silicon layer is formed by epitaxial growth.

12. A method according to claim 11, wherein at least one silicon precursor selected from the group consisting of silane, dichlorosilane, trisilane, and combinations thereof is used during epitaxial growth.

13. A method according to claim 11, wherein N₂ is used as carrier gas during epitaxial growth.

14. A method according to claim 11, wherein a trisilane silicon precursor and a N₂ carrier gas are used during epitaxial growth.

15. A passivated semiconductor substrate prepared according to the method of claim 1.

16. A passivated semiconductor substrate according to claim 13, having an Omhic current-voltage profile which can be measured by a spreading resistance analysis technique.

17. Use of a passivated semiconductor substrate according to claim 13 in a semiconductor device.
